(19) United States
(12) Patent Application Publication
(10) Pub. No.: US 2023/0419475 A1
(43) Pub. Date: Dec. 28, 2023

(54) INFORMATION PROCESSING METHOD, NON-TRANSITORY COMPUTER READABLE RECORDING MEDIUM AND INFORMATION PROCESSING DEVICE

(71) Applicant: Panasonic Intellectual Property Corporation of America, Torrance, CA (US)

(72) Inventors: Yumiko SHINOHARA, Kyoto (JP); Masafumi ISHIKAWA, Tokyo (JP); Yuki WATANABE, Kanagawa (JP); Saeko SHINGU, Osaka (JP); Hiroki TAKEUCHI, Osaka (JP)

(73) Assignee: Panasonic Intellectual Property Corporation of America, Torrance, CA (US)

(21) Appl. No.: 18/368,109

(22) Filed: Sep. 14, 2023

Related U.S. Application Data
(63) Continuation of application No. PCT/JP2021/048596, filed on Dec. 27, 2021.

(30) Foreign Application Priority Data
Mar. 18, 2021 (JP) 2021-044748

(51) Int. Cl. G06T 7/00; G06F 30/18; G06K 7/14

(52) U.S. Cl. CPC G06T 7/0008; G06F 30/18; G06K 7/1417

(57) ABSTRACT

A management server 1 acquires identification information of an apparatus; acquires association information associated with the acquired identification information from a memory, the association information including a structural diagram showing a structure of a facility, an installation location of the apparatus in the facility, and an installation procedure of the apparatus; generates installation information including an installation screen on which the installation location is indicated on the acquired structural diagram, and the acquired installation procedure; outputs the installation information; and when detecting that the installation procedure of the apparatus has ended up to a first procedure, outputs connection confirmation information for performing a connection confirmation work for a wire connection of the apparatus.

### TECHNICAL FIELD

The present invention relates to a technique for supporting installation of an apparatus.

### BACKGROUND ART

In an apparatus to which a large number of wire rods are connected, it is difficult to correctly wire-connect the wire rods. Therefore, Patent Literature 1 discloses a technique of: reading, by a reader, a wire number (barcode) of a wire rod, the wire number being attached to the wire rod for specifying information of a connection destination; and displaying a wire connection position of an apparatus as a connection destination of the wire rod corresponding to the read wire number.

Furthermore, Patent Literature 1 discloses a technique of again reading, by the reader, a number of a wire rod whose connection work has ended to confirm whether the wire rod is connected to a correct position or not.

However, in Patent Literature 1, further improvement is required in order to reduce time and labor in installing the apparatus.

### CITATION LIST

### Patent Literature

Patent Literature 1: JP 5564444 B Summary of Invention

The present invention has been made to solve such a problem, and an object of the present invention is to provide a technique enabling reduction in time and labor when installing an apparatus in a facility.

An information processing method in one aspect of the present invention is an information processing method in an information processing device that supports installation of an apparatus in a facility, the method including: by a processor of the information processing device, acquiring identification information of the apparatus; acquiring association information associated with the acquired identification information from a memory, the association information including a structural diagram showing a structure of the facility, an installation location of the apparatus in the facility, and an installation procedure of the apparatus; generating installation information including an installation screen on which the installation location is indicated on the acquired structural diagram, and the acquired installation procedure; outputting the installation information; and when detecting that an installation work of the apparatus has ended up to a first procedure, outputting connection confirmation information for performing a connection confirmation work for a wire connection of the apparatus.

According to the present invention, it is possible to reduce time and labor when installing an apparatus in a facility.

### BRIEF DESCRIPTION OF DRAWINGS

FIG. 1 is a block diagram illustrating an example of a configuration of an information processing system in a first embodiment of the present disclosure.

FIG. 2 is a diagram illustrating an example of a configuration of a management server in the embodiment of the present disclosure.

FIG. 3 is a block diagram illustrating an example of a configuration of a user terminal in the embodiment of the present disclosure.

FIG. 4 is a block diagram illustrating an example of a configuration of an order server in the embodiment of the present disclosure.

FIG. 5 is a block diagram illustrating an example of a configuration of a display terminal in the embodiment of the present disclosure.

FIG. 6 is a diagram illustrating an example of a data configuration of an apparatus data base.

FIG. 7 is a sequence diagram illustrating an example of processing of the information processing system in the embodiment of the present disclosure.

FIG. 8 is a sequence diagram following FIG. 7.

FIG. 9 is a sequence diagram following FIG. 8.

FIG. 10 is a view illustrating various screens displayed on a display terminal before a recognition code is captured.

FIG. 11 is a view illustrating a first installation information screen displaying installation information.

FIG. 12 is a view illustrating a second installation information screen displaying the installation information.

FIG. 13 is a view illustrating a connection confirmation information screen displaying connection confirmation information.

FIG. 14 is a view illustrating the connection confirmation information screen displayed when a wire connection is incorrect.

FIG. 15 is a view illustrating a connection confirmation end screen.

FIG. 16 is a flowchart illustrating an example of processing of the management server in the embodiment of the present disclosure.

FIG. 17 is a flowchart illustrating an example of connection confirmation processing.

FIG. 18 is a diagram illustrating a wire connection image of a correctly wire-connected apparatus.

FIG. 19 is a diagram illustrating a wire connection image of an apparatus that is not correctly wire-connected.

FIG. 20 is a sequence diagram illustrating an example of processing of the information processing system in a case of displaying a wire connection image in response to a request of a user.

FIG. 21 is a diagram illustrating an apparatus search screen.

### DESCRIPTION OF EMBODIMENTS

### (Knowledge Underlying Present Disclosure)

A smart home that realizes a safer and more comfortable life for a resident has been studied by making full use of technologies such as Internet of Things (IoT) and Artificial Intelligence (AI).

In a case where IoT apparatuses are installed in a smart home, since there are few constructors who are familiar with installation and connection of IoT apparatuses, installation and connection errors are likely to occur. Furthermore, specifying a cause of a connection failure of an IoT apparatus is complicated, and it is therefore important to reduce errors at the time of installation. Therefore, it is required to support a constructor so that installation of an apparatus and connection confirmation of the apparatus can be easily performed without depending on a technical level of the constructor.

Patent Literature 1 described above discloses the technique of reducing connection errors by reading, with a reader, a wire number (barcode) of a wire rod, the wire number being attached to the wire rod for specifying information of a connection destination; and displaying a wire connection position of an apparatus as a connection destination of the wire rod corresponding to the read wire number.

However, Patent Literature 1 has a problem that it is necessary to read again, with the reader, a wire number at the stage of a connection confirmation work after the wire number is read with the reader at a stage of a work for connecting the wire rod to the apparatus, which is troublesome.

Furthermore, although in Patent Literature 1, a two-dimensional screen, a three-dimensional screen, or a photograph of a position where the apparatus to which the wire rod is connected is attached is displayed, the displayed screen is a screen indicating an attachment position of the apparatus to which the wire rod is connected in a control panel, and a screen indicating an installation location of the apparatus in a facility is not displayed. Therefore, Patent Literature 1 has a problem that a constructor cannot easily grasp an installation location of an apparatus in a facility.

The present disclosure has been made to solve such a problem, and an object of the present disclosure is to provide a technique enabling reduction in time and labor when installing an apparatus in a facility.

An information processing method in one aspect of the present disclosure is an information processing method in an information processing device that supports installation of an apparatus in a facility, the method including: by a processor of the information processing device, acquiring identification information of the apparatus; acquiring association information associated with the acquired identification information from a memory, the association information including a structural diagram showing a structure of the facility, an installation location of the apparatus in the facility, and an installation procedure of the apparatus; generating installation information including an installation screen on which the installation location is indicated on the acquired structural diagram, and the acquired installation procedure; outputting the installation information; and when detecting that an installation work of the apparatus has ended up to a first procedure, outputting connection confirmation information for performing a connection confirmation work for a wire connection of the apparatus.

According to this configuration, the identification information of the apparatus is acquired, the structural diagram of the facility associated with the acquired identification information, the installation location of the apparatus in the facility, and the installation procedure of the apparatus are acquired from the memory, the installation information including the installation screen indicating the installation location on the acquired structural diagram and the installation procedure of the apparatus is generated, and the generated installation information is output. Therefore, the constructor who has checked the installation information can easily confirm the installation location of the apparatus in the facility and the installation procedure of the apparatus. Furthermore, when it is detected that the installation work has ended up to the first procedure, the connection confirmation information for performing the connection confirmation work for a wire connection of the apparatus is output. This enables the constructor to perform the connection confirmation work without imposing, on the constructor, a work of again acquiring the identification information from the apparatus using a reading device at the time of performing the connection confirmation work. As described above, the present configuration enables reduction in time and labor required for installing an apparatus in a facility.

In the above-described information processing method, the apparatus may include an embedded apparatus in which a wire connection location is embedded in a wall of the facility, an installation work of the embedded apparatus may include a second procedure that is a procedure to be executed later than the first procedure, the second procedure being a work of embedding the apparatus into the wall.

When the apparatus is embedded in the wall, it is difficult to confirm whether or not the wire connection is correct because the wire connection location is embedded in the wall. According to this configuration, in a case of an embedded apparatus, the connection confirmation information is output when the first procedure performed at timing before the second procedure ends, the second procedure being the work of embedding the embedded apparatus in the wall. This enables the constructor to perform the connection confirmation work in a state where the wire connection location is exposed, which facilitates the connection confirmation work.

In the above-described information processing method, the connection confirmation work may include an imaging work of capturing an image of a wire connection of the apparatus with an imaging device, and the method may further include acquiring a wire connection image captured in the imaging work.

According to the present configuration, since the wire connection of the apparatus is captured by the imaging device to acquire the captured wire connection image, it is possible to confirm whether or not the wire connection is correct based on the wire connection image. In the above-described information processing method, in the acquisition of the wire connection image, the acquired wire connection image may be stored in the memory, and the method may further include outputting the wire connection image in response to an acquisition request for the wire connection image.

According to this configuration, the wire connection image is output in response to the acquisition request. This enables a person different from the constructor to browse the wire connection image, thereby facilitating handover of apparatus management from the constructor to the person. In addition, the acquisition request for the wire connection image may be made in order to confirm a construction work performed by the constructor himself/herself.

The above-described information processing method may further include acquiring the wire connection image captured in the connection confirmation work, determining whether or not the wire connection is correct based on the wire connection image, and outputting a determination result of the wire connection.

According to the present configuration, since determination is made whether or not the wire connection is correct based on the wire connection image to output a determination result of the wire connection, it is possible to notify the constructor of whether or not the wire connection is correct without imposing a work of determining whether or not the wire connection is correct on the constructor.

The above-described information processing method may further include, in a case where the wire connection is determined to be incorrect in determination of the wire connection, outputting the installation information again.

According to this configuration, in a case where the wire connection is incorrect, it is possible to cause the constructor to perform the installation work again.

In the above-described information processing method, the memory may store in advance connection type information indicating whether the apparatus is a wired apparatus to be connected by a cable or a wireless apparatus not to be connected by a cable, the method may further include determining whether the apparatus is the wired apparatus or the wireless apparatus based on the connection type information, and the connection confirmation information to be output when the apparatus is determined to be the wired apparatus may include information urging the connection confirmation work, and the connection confirmation information to be output when the apparatus is determined to be the wireless apparatus may include information indicating that the connection confirmation work is unnecessary.

According to the present configuration, since in a case where the apparatus is a wired apparatus, when the installation work ends up to the first procedure, the connection confirmation information urging the connection confirmation work is output, it is possible to cause the constructor to smoothly perform the connection confirmation work for the wired apparatus. In a case where the apparatus is a wireless apparatus, when the installation work ends up to the first procedure, the connection confirmation information including the information indicating that the connection confirmation work is unnecessary is output. Therefore, the installation work can be ended without imposing the connection confirmation work on the constructor for the wireless apparatus that does not require the connection confirmation work.

In the above-described information processing method, the structural diagram may be a floor plan that two-dimensionally or three-dimensionally displays the structure of the facility.

According to the present configuration, since the structural diagram is a floor plan displaying the structure of the facility two-dimensionally or three-dimensionally, it is possible to display the installation location of the apparatus on the floor plan, thereby allowing the constructor to easily confirm the installation location.

In the above-described information processing method, the installation information and the connection confirmation information may be displayed on a display terminal of a constructor of the apparatus.

According to this configuration, since the installation information and the connection confirmation work are displayed on the display terminal of the constructor, the constructor can smoothly perform the installation work of the apparatus.

In the above-described information processing method, the apparatus is provided with a recognition code, and the identification information is generated based on the recognition code read by a display terminal of a constructor.

According to this configuration, the constructor can obtain the installation information and the connection confirmation information only by performing the work of causing the display terminal to read the recognition code provided in the apparatus.

A program in another aspect of the present disclosure is a program of an information processing device that supports installation of an apparatus in a facility, the program causing a computer of the information processing device to execute processing of: acquiring identification information of the apparatus; acquiring association information associated with the acquired identification information from a memory, the association information including a structural diagram showing a structure of the facility, an installation location of the apparatus in the facility, and an installation procedure of the apparatus; generating installation information including an installation screen on which the installation location is indicated on the acquired structural diagram, and the acquired installation procedure; outputting the installation information; and when detecting that an installation work of the apparatus has ended up to a first procedure, outputting connection confirmation information for performing a connection confirmation work of a wire connection of the apparatus.

The present configuration enables providing a program that can obtain an effect similar to that of the information processing method described above.

An information processing device in yet another aspect of the present disclosure is an information processing device that supports installation of an apparatus in a facility, and includes: an acquisition unit that acquires identification information of the apparatus; a generation unit that acquires association information associated with the acquired identification information from a memory, the association information including a structural diagram showing a structure of the facility, an installation location of the apparatus in the facility, and an installation procedure of the apparatus, and generates installation information including an installation screen on which the installation location is indicated on the acquired structural diagram, and the acquired installation procedure; a first output unit that outputs the installation information; and a second output unit that outputs connection confirmation information for performing a connection confirmation work for a wire connection of the apparatus when detecting that an installation work for the apparatus has ended up to a first procedure.

The present configuration enables providing an information processing device that can obtain an effect similar to that of the information processing method described above.

The present disclosure can also be implemented as an information processing system that operates by such a computer program as described above. In addition, it is needless to say that such a computer program can be distributed using a computer-readable non-transitory recording medium such as a CD-ROM, or via a communication network such as the Internet.

Each of embodiments to be described below illustrates a specific example of the present disclosure. Numerical values, shapes, constituent elements, steps, an order of steps, and the like shown in the embodiments below are merely examples, and are not intended to limit the present disclosure. Furthermore, among constituent elements in the embodiments below, a constituent element that is not described in an independent claim indicating the most significant concept will be described as an optional constituent element. Furthermore, in all the embodiments, the respective contents can be combined.

### EMBODIMENT

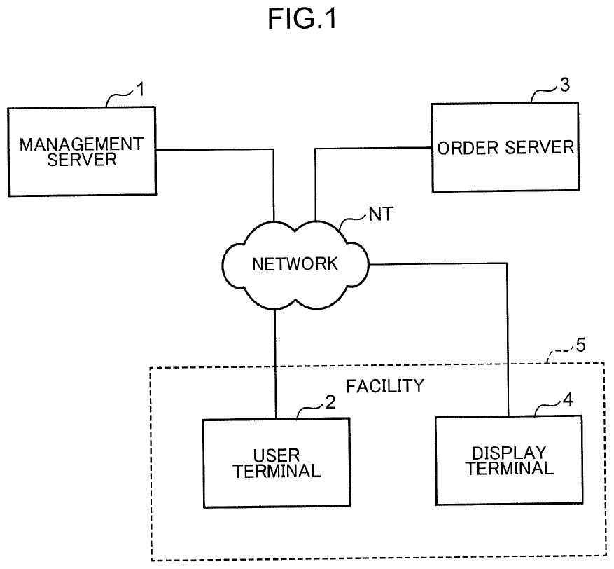

FIG. 1 is a block diagram illustrating an example of a configuration of an information processing system in a first embodiment of the present disclosure. The information processing system includes a management server 1 (an example of an information processing device), a user terminal 2, an order server 3, and a display terminal 4. The information processing system is a system that supports installation of an apparatus in a facility 5. The management server 1, the user terminal 2, the order server 3, and the display terminal 4 are communicably connected to each other via a network NT. The network NT is configured with, for example, a wide area communication network including an Internet communication network and a mobile phone communication network. As the apparatus, for example, an IOT apparatus which is an electrical appliance having a communication function can be adopted. For example, the apparatus includes a personal computer, a refrigerator, a washing machine, a television set, an air conditioner, and the like.

The facility 5 is a house, for example. The house may be an apartment house or a detached house. Alternatively, the facility 5 may be an office. Although one facility 5 is illustrated in FIG. 1, a plurality of facilities 5 may be provided.

The management server 1 is configured with, for example, a cloud server including one or a plurality of computers. The management server 1 manages an apparatus already installed in the facility 5 and an apparatus to be installed.

The user terminal 2 is configured with, for example, a portable information terminal such as a smartphone and a tablet computer, or a stationary information terminal. The user terminal is a terminal owned by a user. In a case where the facility 5 is a house, the user is a resident of the facility 5. When the facility 5 is an office, the user is an office manager.

The order server 3 is configured with, for example, a cloud server including one or a plurality of computers. The order server 3 is, for example, a server that operates a sales site of an apparatus opened on the Internet. The order server 3 accepts an order request for the apparatus performed by the user using the user terminal 2. The ordered apparatus is delivered to the facility 5.

The display terminal 4 is configured with, for example, a portable information terminal such as a smartphone, a tablet computer, or the like. The display terminal 4 is carried by, for example, a constructor. The constructor is a person who installs an apparatus in a facility. For example, the constructor may be a worker of a business company which specializes in installation work of apparatus. Alternatively, the constructor may be a coordinator who coordinates interiors of a facility.

Although it has been described here that the user and the constructor are different persons, the user may be the constructor. In this case, the constructor need only order an apparatus from the order server 3 using the display terminal 4, which eliminates a need of the user terminal 2. Alternatively, the constructor may be a user. In this case, the user may install the apparatus by referring to various pieces of information displayed on the user terminal 2, which eliminates the need of the display terminal 4.

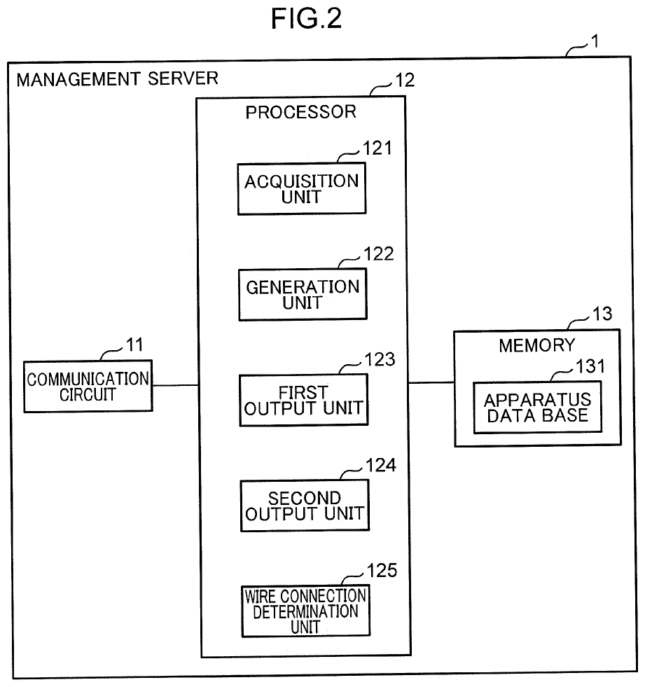

FIG. 2 is a diagram illustrating an example of a configuration of the management server 1 in the embodiment of the present disclosure. The management server 1 includes a communication circuit 11, a processor 12, and a memory 13. The communication circuit 11 is an electric circuit that connects the management server 1 to the network NT. The processor 12 is configured with an integrated circuit such as a central processing unit (CPU) and a field programmable gate array (FPGA). The processor 12 includes an acquisition unit 121, a generation unit 122, a first output unit 123, a second output unit 124, and a wire connection determination unit 125.

The acquisition unit 121 acquires an apparatus code of an apparatus. The apparatus code is identification information for uniquely identifying an apparatus. For example, the apparatus code is a manufacturing number of the apparatus. The apparatus is provided with a recognition code. The apparatus code is generated based on the recognition code read by a camera 46 of the display terminal 4. The recognition code is, for example, a QR code (registered trademark) or a barcode printed on or affixed to a predetermined position such as a housing of an apparatus to be installed.

The display terminal 4 converts a captured recognition code into an apparatus code by performing image processing. The converted apparatus code is transmitted from the display terminal 4 to the management server 1. Thus, the acquisition unit 121 acquires the apparatus code. Alternatively, the display terminal 4 may convert a recognition code input by the constructor through an operation unit 45 (an example of an input device) into an apparatus code and transmit the apparatus code to the management server 1.

The generation unit 122 acquires association information associated with an apparatus code acquired by the acquisition unit 121 from an apparatus data base 131 stored in the memory 13. The association information includes a floor plan of the facility 5, an installation location of the apparatus, and an installation procedure of the apparatus. Then, the generation unit 122 generates installation information including an installation screen on which an installation location is shown on the acquired floor plan and the acquired installation procedure.

The floor plan (an example of a structural diagram) is image data indicating arrangement of rooms and sections inside the facility 5. The floor plan may be a two-dimensional floor plan that two-dimensionally represents the structure of the facility 5 or a three-dimensional floor plan that three-dimensionally represents the structure of the facility 5. The floor plan shows a position of the facility 5 using coordinates represented by two axes of an X axis and a Y axis or coordinates represented by three axes of the X axis, the Y axis, and a Z axis. The X axis indicates, for example, a lateral direction of the facility 5 in top view, the Y axis indicates, for example, a longitudinal direction of the facility 5 in top view, and the Z axis indicates a height direction of the facility. The X axis, the Y axis, and the Z axis are orthogonal to each other.

The installation location is position data indicating an installation location of an apparatus in the facility 5. The position data is, for example, two-dimensional or three-dimensional coordinates on the floor plan.

The installation procedure is data indicating a procedure to install the apparatus at the installation position of the facility 5.

The first output unit 123 transmits (outputs) the installation information generated by the generation unit 122 to the display terminal 4 using the communication circuit 11.

When detecting that the installation work of the apparatus has ended up to a first procedure, using the communication circuit 11, the second output unit 124 transmits (outputs), to the display terminal 4, connection confirmation information for performing a connection confirmation work for a wire connection of the apparatus.

In a case where the apparatus is an embedded apparatus, the first procedure corresponds to, for example, a procedure executed before a work of embedding the apparatus in a wall. The embedded apparatus is, for example, an apparatus having a part thereof such as a back surface embedded in a wall. The procedure before the work of embedding the apparatus in the wall corresponds to, for example, a wire connection procedure of connecting a cable drawn out from a hole of the wall to a terminal of the apparatus. In the case where the apparatus is an embedded apparatus, it is desirable to set a work immediately before embedding the apparatus in the wall as the first procedure.

In a case where the apparatus is a stationary apparatus, the first procedure corresponds to, for example, a final procedure of the installation work. The stationary apparatus is an apparatus other than an embedded apparatus, and is an apparatus installed in furniture and provision set in a facility, such as a desk, or an apparatus installed on a floor or the like.

In addition, the second output unit 124 determines whether the apparatus is a wired apparatus or a wireless apparatus based on connection type information to be described later. Then, when determining that the apparatus is a wired apparatus, the second output unit 124 outputs the connection confirmation information including information urging the connection confirmation work to the display terminal 4, and when determining that the apparatus is a wireless apparatus, the second output unit outputs the connection confirmation information including information indicating that the connection confirmation work is unnecessary to the display terminal 4.

The wired apparatus is an apparatus wire-connected by a cable. Examples of the cable include a communication cable and a power cable. For example, in addition to a wired communication apparatus communicably connected by a communication cable, even a wireless communication apparatus to which a power cable is connected corresponds to a wired apparatus.

The wireless apparatus corresponds to an apparatus that does not need to be wire-connected by a cable. For example, a wireless communication apparatus driven by a battery corresponds to the wireless apparatus.

The connection confirmation work is, for example, a work for confirming whether or not a wire connection of the apparatus is correct. The connection confirmation work includes a work of capturing an image of a wire connection of the apparatus with the camera 46 of the display terminal 4. For example, the connection confirmation information includes information for urging a constructor to capture an image of a wire connection including at least a connection part between the apparatus and the cable. Examples of the connection part between the apparatus and the cable include a connection part between the power cable and the apparatus and a connection part between the communication cable and the apparatus. The camera 46 is an example of an imaging device that captures an image of a wire connection of an apparatus.

The wire connection determination unit 125 receives (acquires) a wire connection image captured by the display terminal 4 in the connection confirmation work using the communication circuit 11. The wire connection determination unit 125 determines whether or not the wire connection performed by the constructor is correct based on the acquired wire connection image, and transmits (outputs) a determination result to the display terminal 4 using the communication circuit 11. More specifically, the wire connection determination unit 125 inputs the wire connection image to a verification model corresponding to a type of the target apparatus, and determines whether or not the wire connection is correct. The wire connection determination unit 125 determines that the wire connection is incorrect when the cable is not correctly connected to a terminal part of the apparatus in the wire connection image. Among states in which the cable is not correctly connected to the terminal part is, for example, a state in which the cable is removed from the terminal to prevent connection between the cable and the apparatus.

When determining that the wire connection is incorrect, the wire connection determination unit 125 transmits (outputs) the installation information to the display terminal 4 again.

The memory 13 is configured with a storage device such as a hard disk drive and a solid state drive, and stores the apparatus data base 131.

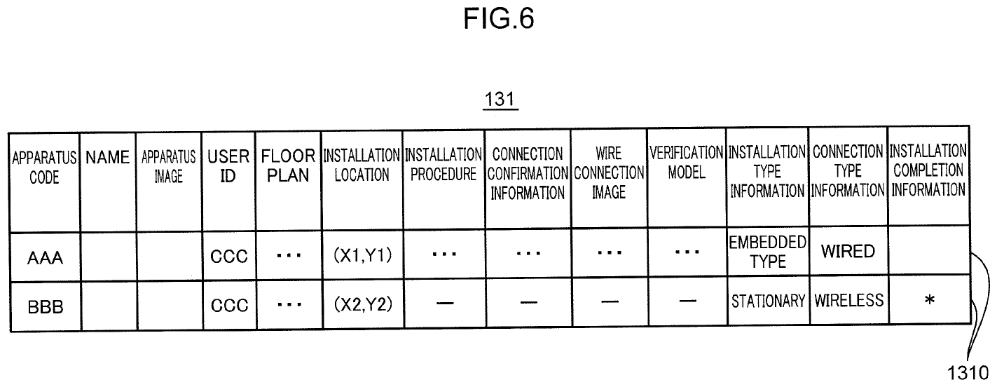

FIG. 6 is a diagram illustrating an example of a data configuration of the apparatus data base 131. The apparatus data base 131 is a data base that manages an installed apparatus in the facility 5 and an apparatus to be installed in the facility 5. In the apparatus data base 131, one record 1310 is allocated to one apparatus. The record 1310 includes the above-described association information. Specifically, the record 1310 stores the apparatus code, a name, an apparatus image, a user ID, the floor plan, the installation location, the installation procedure, the connection confirmation information, the wire connection image, the verification model, installation type information, the connection type information, and installation completion information in association with each other. The apparatus code, the floor plan, the installation location, the installation procedure, and the connection confirmation information have been described above.

The name is a product name of the apparatus, a model number of the apparatus, or a name of the apparatus uniquely assigned by a user. The apparatus image is an image showing an appearance of the apparatus. The user ID is an identifier of a user who has ordered the apparatus. The wire connection image is image data indicating a wire connection location of the wire-connected apparatus. The wire connection image may include a wire connection image that is a sample of the apparatus, or may include a wire connection image captured by a constructor as will be described later.

The verification model is a machine learning model that receives a wire connection image as an input and outputs a wire connection determination result. The verification model is a machine learning model created in advance for each type of apparatus. The verification model is created in advance through machine learning using a wire connection image indicating correct wire connection and a wire connection image indicating incorrect wire connection as learning data. As the machine learning model, for example, a neural network can be adopted. Examples of the determination result of the verification model include correct wire connection, incorrect wire connection, a valid wire connection image, and an invalid wire connection image.

The installation type information is information indicating whether the apparatus is an embedded apparatus or a stationary apparatus. The connection type information is information indicating whether the apparatus is a wired apparatus or a wireless apparatus.

The installation completion information is information indicating whether or not the apparatus has been installed. In a case of an installed apparatus, a symbol “*” is recorded in the field of the installation completion information, and in a case of an apparatus yet to be installed, the field of the installation completion information is blank.

Note that the various data stored in the apparatus data base 131 is not limited to the data illustrated in FIG. 6, and other data may be stored.

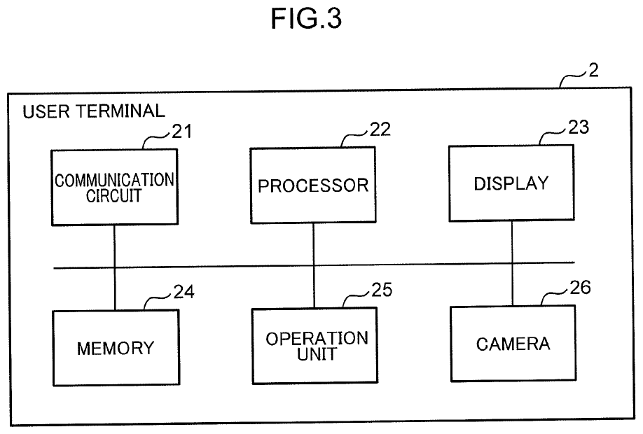

FIG. 3 is a block diagram illustrating an example of a configuration of the user terminal 2 in the embodiment of the present disclosure. The user terminal 2 includes a communication circuit 21, a processor 22, a display 23, a memory 24, an operation unit 25, and a camera 26.

The communication circuit 21 is an electric circuit for connecting the user terminal 2 to the network NT. For example, the communication circuit 21 transmits an order request to the order server 3. The processor 22 is configured with, for example, a CPU and performs overall control of the user terminal 2. The display 23 is configured with a display device such as a liquid crystal display and an organic EL display. For example, the display 23 displays a screen of a sales site of the apparatus. The memory 24 is configured with a nonvolatile rewritable storage device such as a hard disk drive and a solid state drive. The operation unit 25 is configured with a touch panel, and accepts an operation from a user. For example, the operation unit 25 accepts an operation of placing an order for an apparatus from the user. The camera 26 is configured with, for example, a CMOS image sensor.

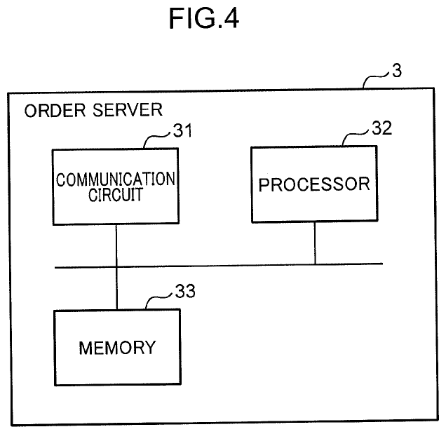

FIG. 4 is a block diagram illustrating an example of a configuration of the order server 3 according to the embodiment of the present disclosure. The order server 3 includes a communication circuit 31, a processor 32, and a memory 33. The communication circuit 31 is an electric circuit for connecting the order server 3 to the network NT. For example, the communication circuit 31 transmits display data for displaying a sales site to the user terminal 2. The communication circuit 31 also transmits order information to the management server 1. The order information is information for notifying the management server 1 of an apparatus to be installed.

The processor 32 is configured with, for example, an integrated circuit such as a CPU and an FPGA, and performs overall control of the order server 3. The memory 33 is configured with, for example, a nonvolatile rewritable storage device such as a flash memory. The memory 33 stores a product data base for managing an apparatus for sale at a sales site.

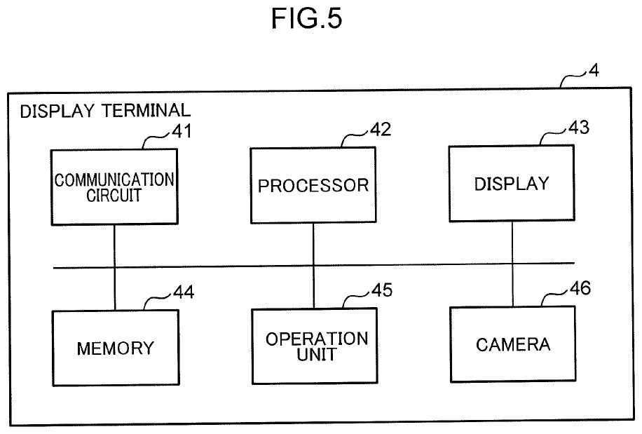

FIG. 5 is a block diagram illustrating an example of a configuration of the display terminal 4 according to the embodiment of the present disclosure. The display terminal 4 includes a communication circuit 41, a processor 42, a display 43, a memory 44, an operation unit 45, and a camera 46. The communication circuit 41 is an electric circuit for connecting the display terminal 4 to the network NT. The processor 42 is configured with, for example, a CPU and performs overall control of the display terminal 4. The display 43 is configured with a display device such as a liquid crystal display and an organic EL display. For example, the display 43 displays various images for supporting installation of the apparatus. The memory 44 is configured with, for example, a nonvolatile rewritable storage device such as a flash memory. The operation unit 45 is configured with a touch panel, and accepts an operation from a constructor. The camera 46 is configured with, for example, a CMOS image sensor. For example, the camera 46 captures the recognition code and a wire connection image.

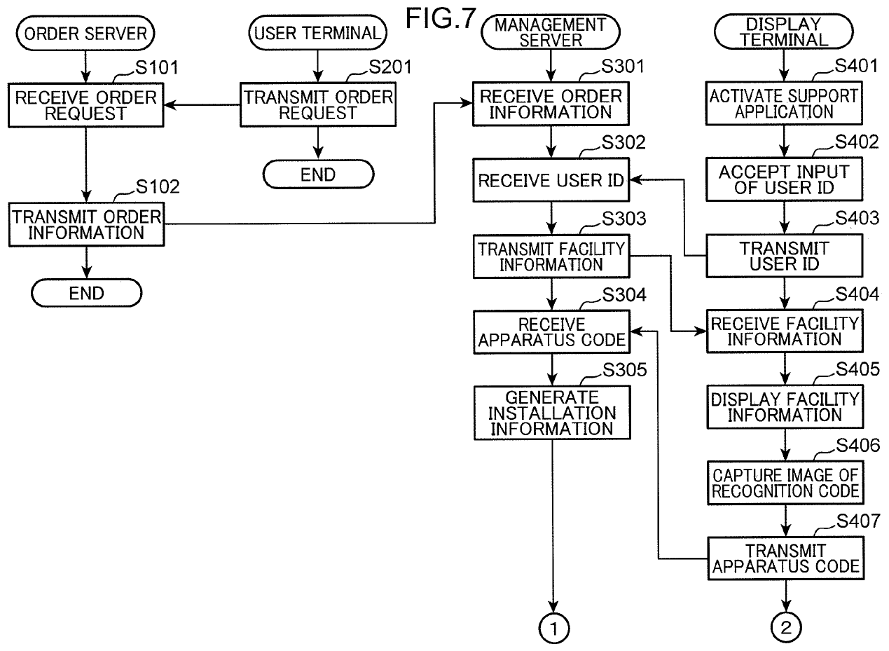

FIG. 7 is a sequence diagram illustrating an example of processing of the information processing system in the embodiment of the present disclosure. In this sequence diagram, an apparatus to be installed is assumed to be a wired apparatus. Each step will be described in detail below.

### (Step S201)

The processor 22 of the user terminal 2 generates an order request for ordering an apparatus selected by the user, and transmits the order request to the order server 3 using the communication circuit 21. The order request includes a name of an apparatus to be ordered, an installation location of the apparatus, and a user ID. Specifically, the operation unit 25 of the user terminal 2 accepts a user's operation of selecting an apparatus to be ordered from among apparatuses displayed in a list on a sales site screen displayed on the display 23. In this operation, the user inputs the installation location of the apparatus to be ordered in the facility 5 and inputs the user ID. For example, the processor 22 of the user terminal 2 acquires an installation location by displaying a floor plan of the facility 5 stored in advance in the memory 24 on the display 23, and causing the user to input an installation location on the displayed floor plan.

### (Steps S101 and S102)

The communication circuit 31 of the order server 3 receives the order request. In Step S102, the processor 32 of the order server 3 generates order information based on the order request, and transmits the generated order information to the management server 1 using the communication circuit 31. The order information includes an apparatus code of an apparatus to he ordered, a name of the apparatus, an installation location of the apparatus, and a user ID. Note that the order information may include an installation procedure of an apparatus to be ordered.

### (Step S301)

The acquisition unit 121 of the management server 1 receives the order information using the communication circuit 11 and records the order information in the apparatus data base 131. Specifically, the acquisition unit 121 creates a new record 1310 corresponding to the ordered apparatus in the apparatus data base 131, and records the order information in the record 1310. As a result, the apparatus code, the name, the user ID, and the installation location of the ordered apparatus are newly recorded in the apparatus data base 131. Note that in the apparatus data base 131, data predetermined according to a type of the apparatus is recorded as the apparatus image, the connection confirmation information, the wire connection image, the verification model, and the installation type information. In addition, regarding the installation procedure, data predetermined for the apparatus may be recorded, or data included in the order information may be recorded.

### (Step S401)

The operation unit 45 of the display terminal 4 accepts an operation from a constructor who activates a support application, and the processor 42 of the display terminal 4 starts the support application. The support application is application software installed in advance in the display terminal 4 to support installation of the apparatus by the constructor. The support application is activated, for example, when an operation of tapping a support application icon is input. When the support application is activated, the display 43 displays a login screen for the management server 1.

### (Step S402)

The operation unit 45 of the display terminal 4 accepts a constructor's operation of inputting the user ID on the login screen. Here, it is assumed that the constructor is notified of the user ID from the user in advance. Note that in a case where the constructor and the user are the same person, the user ID is a constructor ID.

### (Step S403)

The communication circuit 41 of the display terminal 4 transmits the user ID accepted by the operation unit 45 to the management server 1.

### (Step S302)

The acquisition unit 121 of the management server 1 receives the user ID using the communication circuit 11.

### (Step S303)

The generation unit 122 of the management server 1 reads a floor plan corresponding to the user ID and information on an apparatus installed in the facility 5 corresponding to the user ID from the apparatus data base 131, generates facility information including the read floor plan and information on the apparatus, and transmits the generated facility information to the display terminal 4 using the communication circuit 11. The information about the apparatus includes, for example, an apparatus image and a name. Installed apparatuses include not only an installed apparatus but also an apparatus yet to be installed.

### (Step S404)

The communication circuit 41 of the display terminal 4 receives the facility information.

### (Step S405)

The display 43 of the display terminal 4 displays the received facility information.

### (Step S406)

The camera 46 of the display terminal 4 captures the recognition code based on an imaging instruction from the constructor received by the operation unit 45.

### (Step S407)

The processor 42 of the display terminal 4 analyzes the captured recognition code to acquire an apparatus code corresponding to the recognition code, and transmits the apparatus code to the management server 1 using the communication circuit 41.

### (Step S304)

The acquisition unit 121 of the management server 1 receives the apparatus code using the communication circuit 11.

### (Step S305)

The generation unit 122 of the management server 1 acquires association information corresponding to the apparatus code from the apparatus data base 131. The association information includes the floor plan of the facility 5, the installation location of the apparatus to be installed (hereinafter, referred to as target apparatus), and the installation procedure of the apparatus. The generation unit 122 generates installation information including the floor plan, the installation location, and the installation procedure. The installation information further includes an apparatus image and a name of the target apparatus.

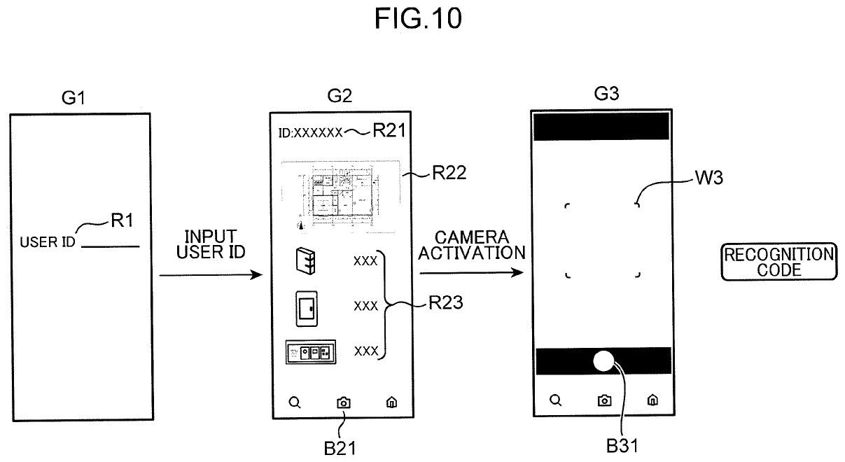

FIG. 10 is a view illustrating various screens displayed on the display terminal 4 before the recognition code is captured. When the support application is activated, the display terminal 4 displays a login screen G1. The login screen G1 is provided with an input field R1 for inputting a user ID.

When the user ID is input in the input field R1 by the constructor, the display terminal 4 displays a facility information screen G2 indicating facility information. The facility information screen G2 includes a display field R21, a floor plan display field R22, and an apparatus list display field R23.

The display field R21 displays the user ID input in the input field R1. The floor plan display field R22 displays a floor plan of the facility 5 corresponding to the user ID. The apparatus list display field R23 displays a list of apparatuses installed in the facility 5 corresponding to the user ID. Here, the apparatus list display field R23 displays a list of apparatus images and apparatus names.

This enables the constructor to confirm a floor plan of the facility 5 in which the constructor himself/herself is currently present, and an installed apparatus and an apparatus to be installed.

A camera button B21 is provided in a lower part of the facility information screen G2. When the user inputs an operation of pressing the camera button B21, the display terminal 4 activates the camera 46 to display an imaging screen G3. The imaging screen G3 includes a frame W3. The constructor adjusts an attitude and a position of the display terminal 4 so that the recognition code provided in the apparatus to be installed falls within the frame W3. Then, when the recognition code falls within the frame W3, the constructor inputs an operation of pressing a shutter button B31 to capture the recognition code. The captured recognition code is converted into an apparatus code by the display terminal 4 and transmitted to the management server 1.

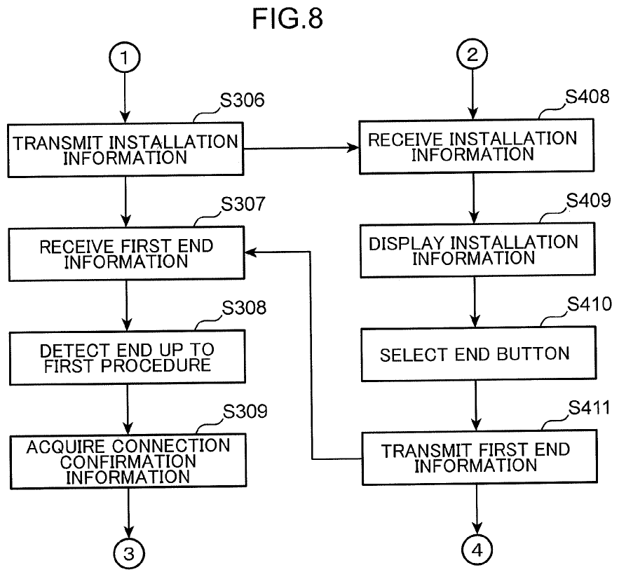

FIG. 8 is a sequence diagram following FIG. 7. Each step will be described in detail below.

### (Step S306)

The first output unit 123 of the management server 1 transmits the installation information using the communication circuit 11.

### (Step S408)

The communication circuit 41 of the display terminal 4 receives the installation information.

### (Step S409)

The display 43 of the display terminal 4 displays the installation information. In the following, the constructor starts the installation work of the target apparatus with reference to the installation information.

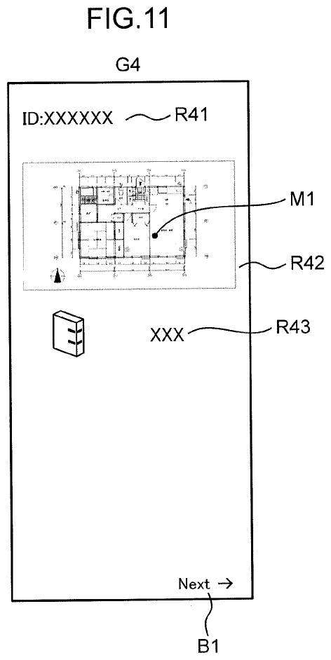

FIG. 11 is a view illustrating a first installation information screen G4 displaying the installation information. The first installation information screen G4 includes a display field R41, a floor plan display field R42, an apparatus display field R43, and a screen transition button B1.

The display field R41 displays a user ID. The floor plan display field R42 displays a floor plan included in the installation information. The apparatus display field R43 displays a target apparatus. Here, the apparatus display field R43 displays an apparatus screen and a name of a target apparatus. This enables the constructor to easily confirm whether or not an apparatus at hand is a target apparatus by comparing the apparatus at hand with the display content of the apparatus display field R43. Furthermore, a mark M1 indicating an installation location of the target apparatus is superimposed and displayed on the floor plan displayed in the floor plan display field R42. This enables the constructor to easily confirm the installation location by comparing a floor plan of an installation site with the position of the mark M1 on the floor plan displayed in the floor plan display field R42.

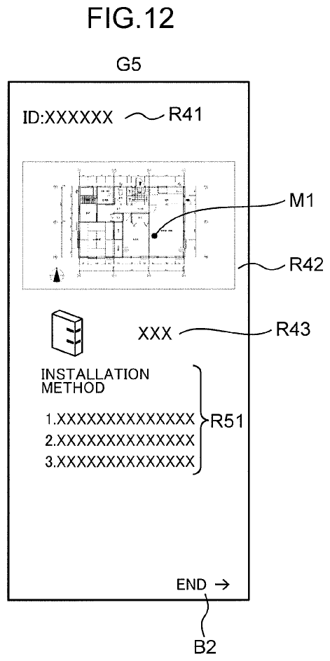

The constructor who has ended confirmation work for the target apparatus with reference to the first installation information screen G4 inputs an operation of pressing the screen transition button B1. When the operation of pressing the screen transition button B1 is input, the display terminal 4 displays a second installation information screen. FIG. 12 is a view illustrating a second installation information screen G5 displaying the installation information. In the second installation information screen G5, the same display fields as those of the first installation information screen G4 are denoted by the same reference numerals, and description thereof will be omitted. The second installation information screen G5 further includes an installation procedure display field R51 and an end button B2 in addition to the display field R41, the floor plan display field R42, and the apparatus display field R43.

The installation procedure display field R51 displays a message indicating an installation procedure of the apparatus up to the first procedure. When the target apparatus is a wired apparatus, the installation procedure display field R51 displays, for example, a procedure of taking out the target apparatus from a box, a procedure of checking accessories and the like, a procedure of assembling the target apparatus as necessary, a procedure of wire-connecting cables to the target apparatus, and the like in order of work.

When the target apparatus is a wireless apparatus, the installation procedure display field R51 displays, for example, the procedure of taking out the target apparatus from the box, the procedure of checking accessories and the like, the procedure of assembling the target apparatus as necessary, a procedure of attaching a battery, and the like in the order of work.

The constructor performs the installation work for the target apparatus according to the installation procedure displayed in the installation procedure display field R51. Then, when the installation work shown in the installation procedure ends, the constructor inputs an operation of pressing the end button B2.

The installation procedure display field R51 may display the installation procedure in a manner as follows. The installation procedure display field R51 may display the installation procedure for each procedure, such as first displaying a procedure (1), then displaying a procedure (2), and then displaying a procedure (3). In this case, the display terminal 4 may have a page feed button displayed in the installation procedure display field R51 and switch a procedure to be displayed each time the page feed button is pressed. Alternatively, the installation procedure display field R51 may display a moving image showing the installation work or may display a still image and text showing the installation work. In particular, for a difficult work such as the wire connection work, the installation procedure display field R51 may display images including a moving image and a still image. Alternatively, the display terminal 4 may display a link for accessing a site on which an answer to a question asked when the installation work is unknown may be displayed in the installation procedure display field R51.

The reference is made back to FIG. 8.

### (Step S410)

The operation unit 45 of the display terminal 4 accepts the operation of pressing the end button B2.

### (Step S411)

The communication circuit 41 of the display terminal 4 transmits, to the management server 1, first end information indicating that the installation work has ended up to the first procedure.

### (Step S307)

The second output unit 124 of the management server 1 receives the first end information using the communication circuit 11.

### (Step S308)

Since the first end information is received, the second output unit 124 detects end of the installation work up to the first procedure. When the target apparatus is a wired apparatus, the second output unit 124 may detect that the installation work has ended up to the first procedure by receiving a signal automatically transmitted from the wire-connected wired apparatus using the communication circuit 11. In addition, in a case where a mode of displaying the page feed button in the installation procedure display field R51 is adopted, the first end information may be transmitted when an operation of pressing the page feed button of a page indicating the final procedure is input by the constructor.

### (Step S309)

The second output unit 124 acquires connection confirmation information of the target apparatus from the apparatus data base 131. Here, since the target apparatus is a wired apparatus, the connection confirmation information includes the information urging the connection confirmation work. In a case where the target apparatus is a wireless apparatus, the connection confirmation information includes the information indicating that the connection confirmation is unnecessary.

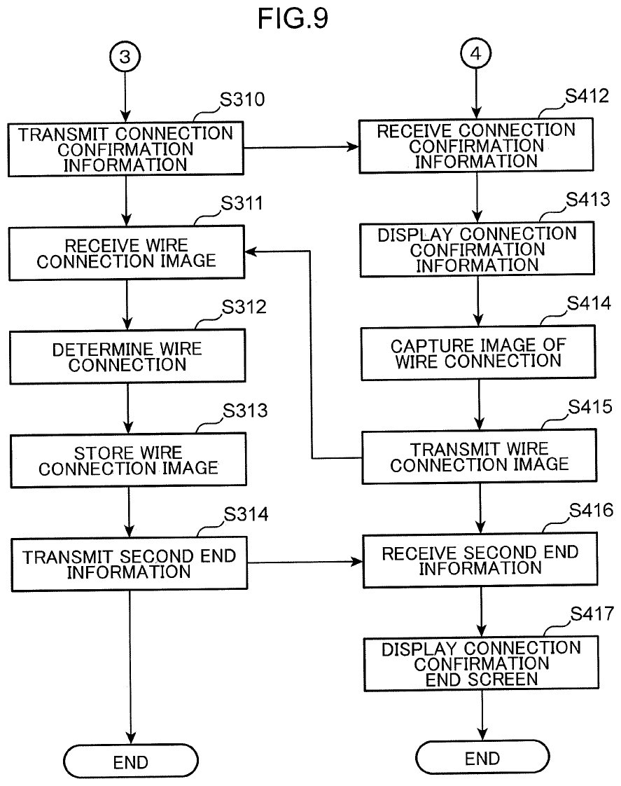

FIG. 9 is a sequence diagram following FIG. 8. Each step will be described in detail below.

### (Step S310)

The second output unit 124 of the management server 1 transmits the connection confirmation information to the display terminal 4 using the communication circuit 11.

### (Step S412)

The communication circuit 41 of the display terminal 4 receives the connection confirmation information.

### (Step S413)

The display 43 of the display terminal 4 displays the connection confirmation information.

### (Step S414)

The camera 46 of the display terminal 4 captures an image of the wire connection of the apparatus.

### (Step S415)

The communication circuit 41 of the display terminal 4 transmits the wire connection image to the management server 1.

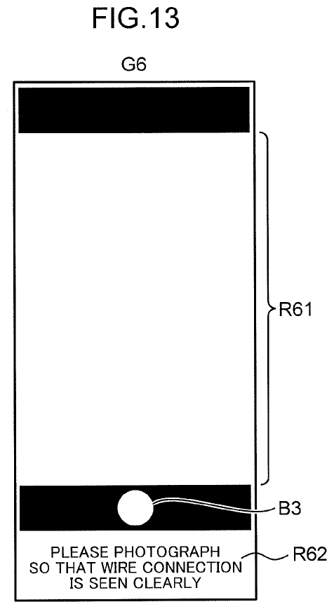

FIG. 13 is a view illustrating a connection confirmation information screen G6 displaying the connection confirmation information. The connection confirmation information screen G6 includes an imaging region R61. When the connection confirmation information screen G6 is displayed, the camera 46 is activated. A display field R62 is provided in a lower part of the connection confirmation information screen G6. In the display field R62, a message is displayed to capture an image of the wire connection with the wire connection part visible in the imaging region R61. As a result, it is possible to urge the constructor to capture an image of the wire connection.

The constructor adjusts the position and the attitude of the display terminal 4 so that the wire connection falls within the imaging region R61. When the adjustment ends, the constructor inputs an operation of pressing an imaging button B3. As a result, a wire connection image is acquired and transmitted to the management server 1. Note that the display terminal 4 may automatically detect that the wire connection falls within the imaging region R61 and capture the image of the wire connection without accepting the operation of the imaging button B3.

In a case where the apparatus is a wireless apparatus, a message indicating that the connection confirmation work is unnecessary is displayed on the display 43 of the display terminal 4 instead of the connection confirmation information screen G6. As this message, for example, “There is no need to perform the connection confirmation work with the camera. This is the end of the installation work.” is adopted. Note that the connection confirmation information screen G6 may have a field for displaying an image as a sample of a wire connection.

The reference is made back to FIG. 9.

### (Step S311)

The wire connection determination unit 125 of the management server 1 receives the wire connection image using the communication circuit 11.

### (Step S312)

The wire connection determination unit 125 inputs the wire connection image to a verification model corresponding to a type of the target apparatus, and determines whether or not the wire connection is correct. Here, it is assumed that a determination result indicating that the wire connection is correct is obtained. Note that in a case where the determination result of the wire connection indicates invalidity of the wire connection image, the wire connection determination unit 125 displays a connection confirmation information screen G7 urging the constructor to capture an image of the wire connection again.

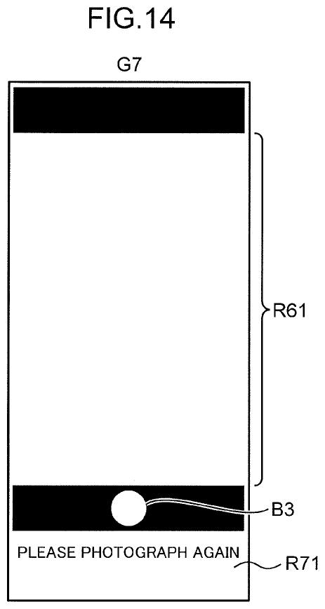

FIG. 14 is a view illustrating the connection confirmation information screen G7 displayed when a wire connection is incorrect. In the connection confirmation information screen G7, the same display fields as those of the connection confirmation information screen G6 are denoted by the same reference numerals, and description thereof will be omitted. In a display field R71, a message indicating that an image of a wire connection part is to be captured again is displayed for the constructor. This enables the constructor to confirm that the wire connection image needs to be captured again.

The reference is made back to FIG. 9.

### (Step S313)

The wire connection determination unit 125 of the management server 1 stores the wire connection image in the apparatus data base 131. Note that in a case where the determination result indicates that the wire connection is incorrect or the wire connection image is invalid, the wire connection determination unit 125 discards the wire connection image.

### (Step S314)

The second output unit 124 transmits second end information indicating the end of the connection confirmation work to the display terminal 4 using the communication circuit 11.

### (Step S416)

The communication circuit 41 of the display terminal 4 receives the second end information.

### (Step S417)

The display 43 of the display terminal 4 displays a connection confirmation end screen G8.

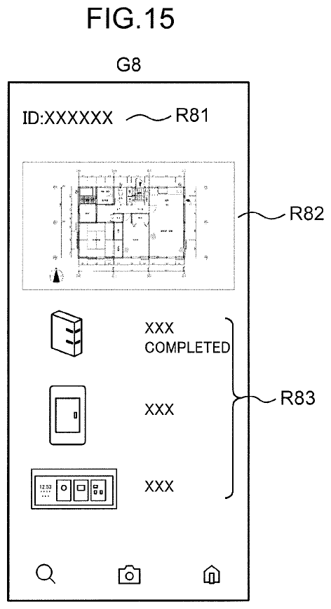

FIG. 15 is a view illustrating the connection confirmation end screen G8. The connection confirmation end screen G8 is a screen for notifying the constructor of the end of the connection confirmation work and the installation work. The connection confirmation end screen G8 includes a display field R81, a floor plan display field R82, and an apparatus list display field R83. The display field R81 and the floor plan display field R82 are the same as the display field R21 and the floor plan display field R22 of the facility information screen G2 illustrated in FIG. 10. The apparatus list display field R83 displays a list of apparatuses installed in the facility 5. Here, the apparatus list display field R83 displays a message “Completed” for the target apparatus. This enables the constructor to confirm that the installation work of the target apparatus has ended.

Note that in a case where there is a plurality of other target apparatuses, the display terminal 4 displays the screens illustrated in FIGS. 10 to 14 on the display 43 with respect to the other target apparatuses, and causes the constructor to perform installation work for the other target apparatuses. Then, when installation of all the target apparatuses is completed, the display terminal 4 may display the connection confirmation end screen G8.

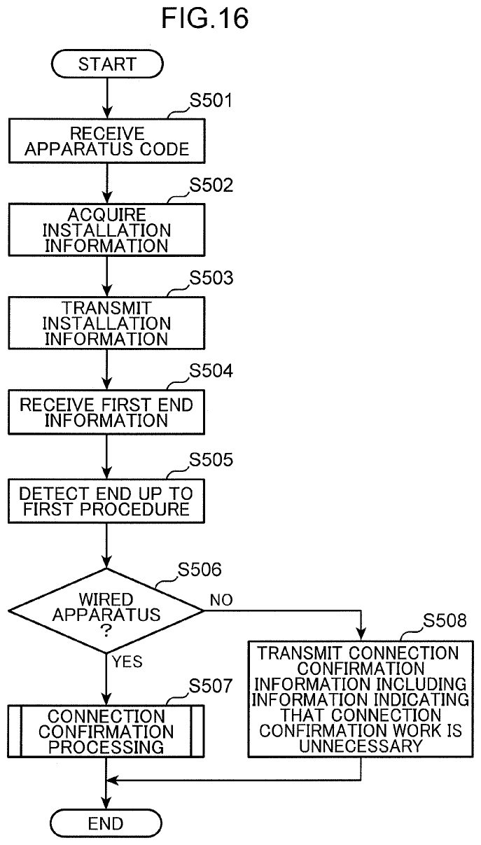

FIG. 16 is a flowchart illustrating an example of processing of the management server 1 in the embodiment of the present disclosure. Each step will be described in detail below.

### (Step S501)

The acquisition unit 121 receives an apparatus code using the communication circuit 11. This processing corresponds to Step S304 described above.

### (Step S502)

The generation unit 122 refers to the apparatus data base 131 and generates installation information of the target apparatus indicated by the apparatus code. This processing corresponds to Step S305 described above.

### (Step S503)

The first output unit 123 transmits the installation information to the display terminal 4 using the communication circuit 11. This processing corresponds to Step S306 described above.

### (Step S504)

The first output unit 123 receives the first end information using the communication circuit 11. This processing corresponds to Step S307 described above.

### (Step S505)

Since the first end information is received, the second output unit 124 detects end of the installation work up to the first procedure. This processing corresponds to Step S308 described above.

### (Step S506)

The second output unit 124 refers to the connection type information of the target apparatus and determines whether or not the target apparatus is a wired apparatus. When the target apparatus is determined to be a wired apparatus (YES in Step S506), connection confirmation processing is executed (Step S507). When the target apparatus is determined to be a wireless apparatus (NO in Step S506), the second output unit 124 transmits the connection confirmation information including the information indicating that the connection confirmation work is unnecessary (Step S508), and ends the processing. In other words, in a case where the target apparatus is a wireless apparatus, wire connection is unnecessary, and connection confirmation work is unnecessary. Therefore, the processing ends here.

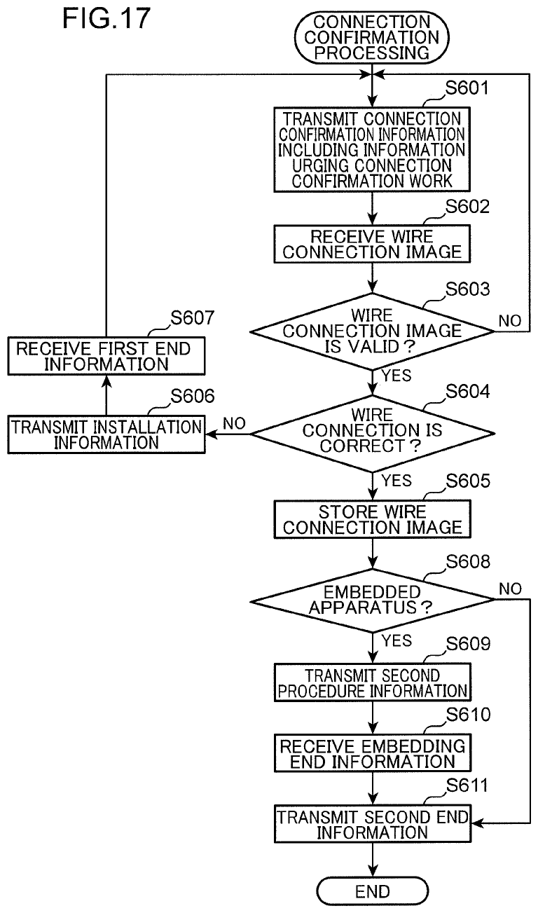

FIG. 17 is a flowchart illustrating an example of the connection confirmation processing. Each step will be described in detail below.

### (Step S601)

The second output unit 124 acquires the connection confirmation information including the information urging the connection confirmation work from the apparatus data base 131, and transmits the connection confirmation information to the display terminal 4 using the communication circuit 11. This processing corresponds to Steps S309 and S310 described above.

### (Step S602)

The wire connection determination unit 125 receives a wire connection image transmitted from the display terminal 4 using the communication circuit 11. This processing corresponds to Step S311 described above.

### (Step S603)

The wire connection determination unit 125 inputs the wire connection image to the verification model, and determines whether or not the wire connection image is valid based on an output determination result. When the wire connection image is determined to be valid (YES in Step S603), the processing proceeds to Step S604. On the other hand, when the wire connection image is determined to be invalid (NO in Step S603), the processing returns to Step S601. In this case, the image of the wire connection is captured again by the constructor, and the wire connection image is transmitted from the display terminal 4. An image being valid means that the wire connection image has an image quality enough to determine correctness of the wire connection. A wire connection image being invalid means that the wire connection image has an image quality to such an extent that correctness of the wire connection cannot be determined. The processing in Steps S603 and S604 corresponds to the above-described Step S312.

### (Step S604)

The wire connection determination unit 125 determines whether or not the wire connection is correct based on the determination result output from the verification model. When the wire connection is determined to be correct (YES in Step S604), the wire connection determination unit 125 stores the wire connection image in the apparatus data base 131 (Step S605). The processing of Step S605 corresponds to Step S313 described above. On the other hand, when the wire connection is determined to be incorrect (NO in Step S604), the wire connection determination unit 125 advances the processing to Step S606.

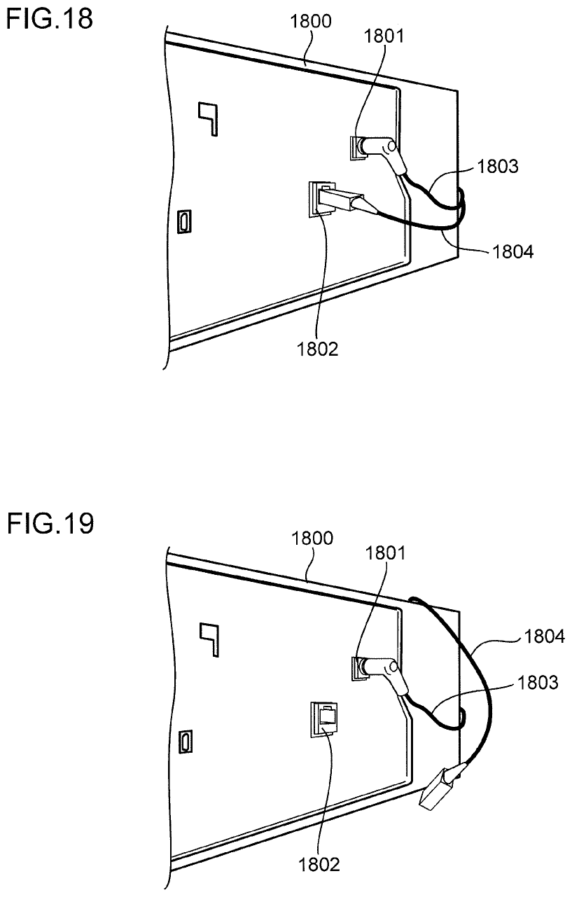

FIG. 18 is a diagram illustrating a wire connection image of a correctly wire-connected apparatus 1800. The apparatus 1800 is, for example, a stationary computer. The apparatus 1800 includes a power terminal 1801 and a communication terminal 1802. The power terminal 1801 and the communication terminal 1802 are provided on a back surface of the apparatus 1800. A power cable 1803 is connected to the power terminal 1801. The power cable 1803 is a cable that supplies power to the apparatus 1800. A communication cable 1804 is connected to the communication terminal 1802. The communication cable 1804 is, for example, a LAN cable. The apparatus 1800 is connected to a local area network in the facility 5 via the communication cable 1804. In a wire connection image of FIG. 18, the power cable 1803 and the communication cable 1804 are correctly wire-connected. Therefore, a verification model to which the wire connection image illustrated in FIG. 18 is input determines that the wire connection is correct.

FIG. 19 is a diagram illustrating a wire connection image of the apparatus 1800 that is not correctly wire-connected. In the example of FIG. 19, while the power cable 1803 is connected to the power terminal 1801, the communication cable 1804 is not connected to the communication terminal 1802. Therefore, a verification model to which the wire connection image illustrated in FIG. 19 is input determines that the wire connection is incorrect.

The reference is made back to FIG. 17.

### (Step S606)

The first output unit 123 again transmits the installation information of the target apparatus to the display terminal 4 using the communication circuit 11. As a result, the first installation information screen G4 and the second installation information screen G5 are displayed on the display terminal 4, and the constructor performs the wire connection work again.

When the wire connection work ends, the operation of pressing the end button B2 on the second installation information screen G5 is input by the constructor. With this operation, the first end information is transmitted from the display terminal 4.

### (Step S607)

The second output unit 124 receives the first end information transmitted from the display terminal 4, and returns the processing to Step S601. As a result, determination of the wire connection is made again by the verification model.

### (Step S608)

The second output unit 124 refers to the apparatus data base 131 to determine whether or not the target apparatus is an embedded apparatus. When the target apparatus is an embedded apparatus (YES in Step S608), the second output unit 124 transmits second procedure information indicating a second procedure including an embedding procedure to the display terminal 4 using the communication circuit 11 (Step S609). As a result, the second procedure including the embedding procedure is displayed on the display 43 of the display terminal 4. The constructor performs a work with reference to the displayed second procedure. When the second procedure ends, the constructor inputs an operation of pressing an end button (not illustrated). As a result, embedding work end information indicating the end of the second procedure is transmitted from the display terminal 4. The second procedure may be a procedure including only the embedding procedure. Furthermore, the second procedure may be a procedure made up of a plurality of works including procedures other than the embedding procedure.

### (Step S610)

The second output unit 124 receives the embedding work end information using the communication circuit 11.

### (Step S611)

The second output unit 124 transmits the second end information indicating the end of the installation work and the connection confirmation work to the display terminal 4 using the communication circuit 11. This causes the above-described connection confirmation end screen G8 to be displayed on the display terminal 4. As a result, the constructor can confirm the end of the connection confirmation work.

When the target apparatus is determined not to be an embedded apparatus (NO in Step S608), i.e., when the target apparatus is a stationary apparatus, the second output unit 124 transmits the second end information to the display terminal 4 using the communication circuit 11 without performing the processing of Steps S609 and S610. When the target apparatus is a stationary apparatus, this enables the constructor to end the connection confirmation work without performing the second procedure.

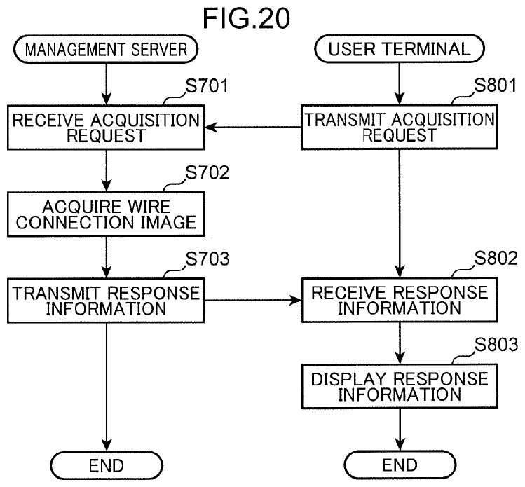

FIG. 20 is a sequence diagram illustrating an example of processing of the information processing system in a case of displaying a wire connection image in response to a user's request. The user appearing in the description of FIG. 20 is a user different from the user who has ordered the apparatus, and corresponds to, for example, a manager who has taken over management of the apparatus from the constructor. Each step will be described in detail below.

### (Step S801)

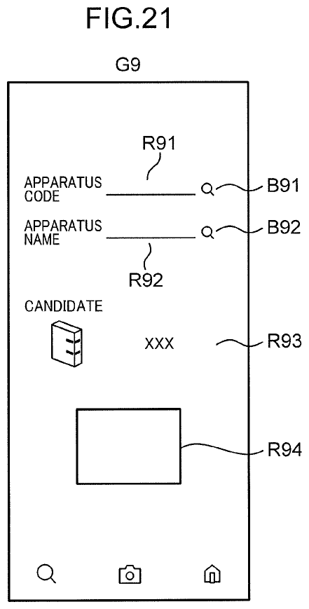

The communication circuit 21 of the user terminal 2 transmits a wire connection image acquisition request. FIG. 21 is a diagram illustrating an apparatus search screen G9. The apparatus search screen G9 is a screen for searching for an apparatus. The apparatus search screen G9 is displayed when the user who has logged in the management server 1 inputs, for example, an operation of pressing a search button B22 on the facility information screen G2 described above.

The apparatus search screen G9 includes an input field R91, an input field R92, a search button B91, a search button B92, an apparatus display field R93, and a wire connection image display field R94. The input field R91 is a field for inputting an apparatus code. The input field R92 is a field for inputting a name of the apparatus. After inputting an apparatus code of an apparatus to be searched into the input field R91, the user inputs an operation of pressing the search button B91. Alternatively, the user inputs an operation of pressing the search button B92 after inputting a name of the apparatus to be searched into the input field R92. With this input, the display terminal 4 transmits the acquisition request to the management server 1. The acquisition request includes a user ID and the apparatus code input into the input field R91. Alternatively, the acquisition request includes the user ID and the name of the apparatus input into the input field R92.

The reference is made back to FIG. 20.

### (Step S701)

The acquisition unit 121 of the management server 1 receives the acquisition request using the communication circuit 11.

### (Step S702)

The acquisition unit 121 of the management server 1 refers to the apparatus data base 131 using an apparatus code or a user ID and a name of the apparatus as keys to acquire an apparatus image, a name, and a wire connection image of the apparatus as a search target.

### (Steps S703 and S802)

The acquisition unit 121 of the management server 1 transmits response information including the apparatus image, the name, and the wire connection image to the user terminal 2 using the communication circuit 11. In Step S802, the communication circuit 21 of the user terminal 2 receives the response information.

### (Step S803)

The display 23 of the user terminal 2 displays the response information. The response information is displayed on the apparatus search screen G9. Specifically, the apparatus image and the name included in the response information are displayed in the apparatus display field R93, and the wire connection image included in the response information is displayed in the wire connection image display field R94.

In this manner, by displaying the wire connection image in response to the acquisition request, a person different from the constructor can browse the wire connection image, thereby facilitating handover of apparatus management from the constructor to the person.

In addition, such an acquisition request may be made by the constructor himself/herself. By the constructor himself/herself making the acquisition request and browsing the wire connection image, the constructor can confirm his/her construction work after the end of the work.

As described above, according to the present embodiment, the apparatus code is acquired, the association information associated with the acquired apparatus code is acquired from the memory 13, the association information including the floor plan of the facility 5, the installation location of the apparatus in the facility 5, and the installation procedure of the apparatus, the installation information is generated that includes the installation screen indicating the installation location on the acquired floor plan, and the installation procedure of the apparatus, and the generated installation information is displayed on the display terminal 4. Therefore, the constructor who has checked the installation information can easily confirm the installation location of the apparatus in the facility 5 and the installation procedure of the apparatus. Furthermore, when it is detected that the installation work has ended up to the first procedure, the connection confirmation information for performing the connection confirmation work is output. This enables the constructor to perform the connection confirmation work without imposing, on the constructor, a work of again reading the recognition code using a reading device or an input device at the time of performing the connection confirmation work. As described above, the present embodiment enables reduction in time and labor required for installing an apparatus in a facility.

The following modifications are applicable to the present disclosure.

(1) When determining that the wire connection is incorrect, the wire connection determination unit 125 may decide a cable that is not correctly wire-connected and output information indicating the decided cable to the display terminal 4. For example, the wire connection determination unit 125 may output, to the display terminal 4, a wire connection image that highlights a cable or a terminal that is not correctly wire-connected.

(2) Some wireless communication apparatuses are wirelessly connected to a wireless LAN slave unit connected to a local area network via a cable. In the present disclosure, such a set of a wireless communication apparatus and a wireless LAN slave unit may be treated as a wired apparatus. In this case, the wire connection determination unit 125 may determine whether or not a wire connection of the cable connecting the wireless LAN slave unit to the local area network is correct. Note that in this case, the display terminal 4 may capture an image of a wire connection of the wireless LAN slave unit and transmit the obtained wire connection image to the management server 1.

(3) The wire connection may include not only a wire connection of a cable on an apparatus side but also a wire connection of a cable on a side opposite to the apparatus. In this case, the wire connection determination unit 125 may determine whether or not both the wire connection of the cable on the apparatus side and the wire connection of the cable on the side opposite to the apparatus are correct. Note that in this case, the display terminal 4 may transmit, to the management server 1, a wire connection image obtained by capturing the wire connection of the cable on the apparatus side and a wire connection image obtained by capturing the wire connection of the cable on the side opposite to the apparatus. This enables determination whether or not a wire connection between apparatuses such as a television set and a recorder is correct.

(4) All or some of the blocks included in the processor 12 of the management server 1 may be included in the user terminal 2 or in the display terminal 4.

(5) The first procedure and the second procedure may be continuous procedures or noncontinuous procedures. For example, another procedure or other plurality of procedures may be interposed between the first procedure and the second procedure.

### INDUSTRIAL APPLICABILITY

According to the present disclosure, it is possible to reduce time and labor required when installing an apparatus in a facility, which is useful for a constructor.

1. An information processing method in an information processing device that supports installation of an apparatus in a facility, the method comprising:
by a processor of the information processing device,
acquiring identification information of the apparatus;
acquiring association information associated with the acquired identification information from a memory,
the association information including a structural diagram showing a structure of the facility, an installation location of the apparatus in the facility, and an installation procedure of the apparatus;
generating installation information including an installation screen on which the installation location is indicated on the acquired structural diagram, and the acquired installation procedure;
outputting the installation information; and
when detecting that an installation work of the apparatus has ended up to a first procedure, outputting connection confirmation information for performing a connection confirmation work for a wire connection of the apparatus.

2. The information processing method according to claim 1, wherein
the apparatus includes an embedded apparatus in which a wire connection location is embedded in a wall of the facility, and
an installation work of the embedded apparatus includes a second procedure that is a procedure to be executed later than the first procedure,
the second procedure being a work of embedding the apparatus into the wall.

3. The information processing method according to claim 1, wherein
the connection confirmation work includes an imaging work of capturing an image of a wire connection of the apparatus with an imaging device, and
the method further comprises acquiring a wire connection image captured in the imaging work.

4. The information processing method according to claim 3, wherein
in the acquisition of the wire connection image, the acquired wire connection image is stored in the memory, and
the method further comprises outputting the wire connection image in response to an acquisition request for the wire connection image.

5. The information processing method according to claim 3, further comprising, acquiring the wire connection image captured in the connection confirmation work, determining whether or not the wire connection is correct based on the wire connection image, and outputting a determination result of the wire connection.

6. The information processing method according to claim 3, further comprising, in a case where the wire connection is determined to be incorrect in determination of the wire connection, outputting the installation information again.

7. The information processing method according to claim 1, wherein
the memory stores in advance connection type information indicating whether the apparatus is a wired apparatus to be connected by a cable or a wireless apparatus not to be connected by a cable,
the method further comprises determining whether the apparatus is the wired apparatus or the wireless apparatus based on the connection type information, and
the connection confirmation information to be output when the apparatus is determined to be the wired apparatus includes information urging the connection confirmation work, and the connection confirmation information to be output when the apparatus is determined to be the wireless apparatus includes information indicating that the connection confirmation work is unnecessary.

8. The information processing method according to claim 1, wherein
the structural diagram is a floor plan that two-dimensionally or three-dimensionally displays the structure of the facility.

9. The information processing method according to claim 1, wherein
the installation information and the connection confirmation information are displayed on a display terminal of a constructor of the apparatus.

10. The information processing method according to claim 1, wherein
the apparatus is provided with a recognition code, and
the identification information is generated based on the recognition code read by a display terminal of a constructor.

11. A non-transitory computer readable recording medium storing a program of an information processing device that supports installation of an apparatus in a facility,
the program causing a computer of the information processing device to execute processing of:
acquiring identification information of the apparatus;
acquiring association information associated with the acquired identification information from a memory,
the association information including a structural diagram showing a structure of the facility, an installation location of the apparatus in the facility, and an installation procedure of the apparatus;
generating installation information including an installation screen on which the installation location is indicated on the acquired structural diagram, and the acquired installation procedure;
outputting the installation information; and
when detecting that an installation work of the apparatus has ended up to a first procedure, outputting connection confirmation information for performing a connection confirmation work of a wire connection of the apparatus.

12. An information processing device that supports installation of an apparatus in a facility,
the information processing device comprising:
an acquisition unit that acquires identification information of the apparatus;
a generation unit that acquires association information associated with the acquired identification information from a memory, the association information including a structural diagram showing a structure of the facility, an installation location of the apparatus in the facility, and an installation procedure of the apparatus, and generates installation information including an installation screen on which the installation location is indicated on the acquired structural diagram, and the acquired installation procedure;
a first output unit that outputs the installation information; and
a second output unit that outputs connection confirmation information for performing a connection confirmation work of a wire connection of the apparatus when detecting that an installation work for the apparatus has ended up to a first procedure.
